(19) United States
(12) Patent Application Publication
(10) Pub. No.: US 2020/0075332 A1
(43) Pub. Date: Mar. 5, 2020

(54) Methods Of Forming Silicon-Containing Layers

(71) Applicant: Applied Materials, Inc., Santa Clara, CA (US)

(72) Inventors: Johanes F. Swenberg, Los Gatos, CA (US); Abhishek Dube, Fremont, CA (US); Steven C.H. Hung, Sunnyvale, CA (US); Benjamin Colombeau, San Jose, CA (US)

(21) Appl. No.: 16/558,719

(22) Filed: Sep. 3, 2019

Related U.S. Application Data
(60) Provisional application No. 62/774,557, filed on Dec. 3, 2018.
(60) Provisional application No. 62/726,401, filed on Sep. 3, 2018.

(51) Int. Cl. H01L 21/02; H01L 29/66

(52) U.S. Cl. CPC H01L 21/02664; H01L 29/66545; H01L 21/02068; H01L 29/66795; H01L 21/02238; H01L 21/02164; H01L 21/02532

(57) ABSTRACT

A method of forming a silicon cap which comprises substantially no germanium atoms nor oxygen atoms is disclosed. Methods for controlling the oxidation of a silicon cap layer are also disclosed. Methods of forming a metal gate replacement which utilize the disclosed silicon cap and controlled oxidation are also disclosed.

### CROSS-REFERENCE TO RELATED APPLICATIONS

This application claims priority to U.S. Provisional Application No. 62/774,557, filed Dec. 3, 2018, and U.S. Provisional Application No. 62/726,401, filed Sep. 3, 2018, the entire disclosures of which are hereby incorporated by reference herein.

### TECHNICAL FIELD

Embodiments of the present disclosure generally relate to methods of forming silicon capping layers. Some embodiments relate to methods for the controlled oxidation of a silicon capping layer to form a silicon oxide layer. Some embodiments relate to methods for forming a gate dielectric and metal gate such as a replacement metal gate using the silicon capping layer disclosed herein.

### BACKGROUND

Many processes in semiconductor manufacturing are required to be performed at lower temperatures due to a device's thermal budget. One such instance is in the formation of gates which use a substrate comprising silicon germanium. The germanium atoms may migrate to layers formed on the silicon germanium surface if temperatures exceed a certain threshold. This limits the methods which may be used to form layers on the silicon germanium surface.

Unfortunately, the methods available for silicon deposition often use an elevated temperature. The methods which are able to deposit silicon at temperatures low enough to have good compatibility with silicon germanium often produce low quality silicon films with defects and poor electrical properties.

The manufacturing of replacement metal gates often requires the presence of a thin (about 2 nm) silicon layer on a substrate surface to act as an etch stop. The etch process removes the dummy gates and any silicon oxide (e.g., SiO₂) formed on the silicon layer. Accordingly, it is imperative to effectively control any oxidation of the silicon layer including any parasitic oxidation from other processes or the atmosphere.

Many current processes for controlling the oxidation of the silicon layer involve depositing a silicon oxide layer on the silicon layer to prevent oxidation of the underlying silicon layer. One process comprises the atomic layer deposition of SiO₂ on the silicon layer. Unfortunately, this process often oxidizes the underlying silicon layer while forming the SiO₂ layer.

Therefore, there is a need for methods of low temperature silicon deposition with fewer defects and improved electrical properties. Additionally, there is a need for methods of controlling the oxidation of a silicon layer.

### SUMMARY

One or more embodiment of the disclosure are directed to a method of forming a silicon cap. The method comprises depositing a silicon layer on a surface of a substrate material maintained at a first temperature. The silicon layer is treated at a second temperature without breaking vacuum to form a silicon cap comprising substantially no oxygen atoms.

Additional embodiments of the disclosure are directed to a method of forming a silicon oxide capping layer. The method comprises conformally depositing a silicon layer on a surface of a substrate material. The surface has a three dimensional feature formed thereon. The substrate material comprises SiGe. The silicon layer has a thickness in a range of about 1 nm to about 3 nm. The silicon layer is deposited at a temperature less than or equal to about 700° C. The silicon layer comprises substantially no germanium atoms. The silicon layer is treated without breaking vacuum to form a silicon cap with fewer defects and improved electrical properties relative to the silicon layer. The silicon cap comprises substantially no oxygen atoms nor germanium atoms. The silicon cap is oxidized to form a silicon oxide capping layer on the silicon cap by a controllable, tunable and conformal process.

Further embodiments of the disclosure are directed to a method of forming a gate dielectric and replacement metal gate. The method comprises conformally depositing a silicon layer on a surface of a substrate material. The surface has a three dimensional feature formed thereon. The substrate material comprises SiGe. The silicon layer has a thickness in a range of about 1 nm to about 3 nm. The silicon layer comprises substantially no germanium atoms. The silicon layer is treated without breaking vacuum to form a silicon cap with fewer defects and improved electrical properties relative to the silicon layer. The silicon cap comprises substantially no oxygen atoms nor germanium atoms. The silicon cap is oxidized to form a silicon oxide capping layer on the silicon cap. A dummy poly layer is deposited on the silicon oxide capping layer. The dummy poly layer and the silicon oxide capping layer are removed. A gate dielectric and replacement metal gate is formed on the silicon cap.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flow chart of a method of forming a silicon cap according to one or more embodiment of the disclosure;

FIG. 2 illustrates an exemplary substrate having three dimensional (3D) features formed thereon according to one or more embodiment of the disclosure;

FIG. 3 is a flow chart of a method of forming a silicon oxide capping layer according to one or more embodiment of the disclosure; and

FIG. 4 illustrates a system that can be used to process a substrate according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus for example, where a film/layer or partial film/layer has been deposited onto a substrate surface, the exposed surface of the newly deposited film/layer becomes the substrate surface.

Some embodiments of the present disclosure relate to methods for forming a silicon cap. Some methods of this disclosure advantageously provide methods for forming a silicon cap at lower temperatures. Some methods of this disclosure advantageously provide for forming a silicon cap with reduced defects and improved electrical properties. Some methods of this disclosure advantageously provide for silicon caps with substantially no oxygen atoms or substantially no oxygen atoms nor germanium atoms.

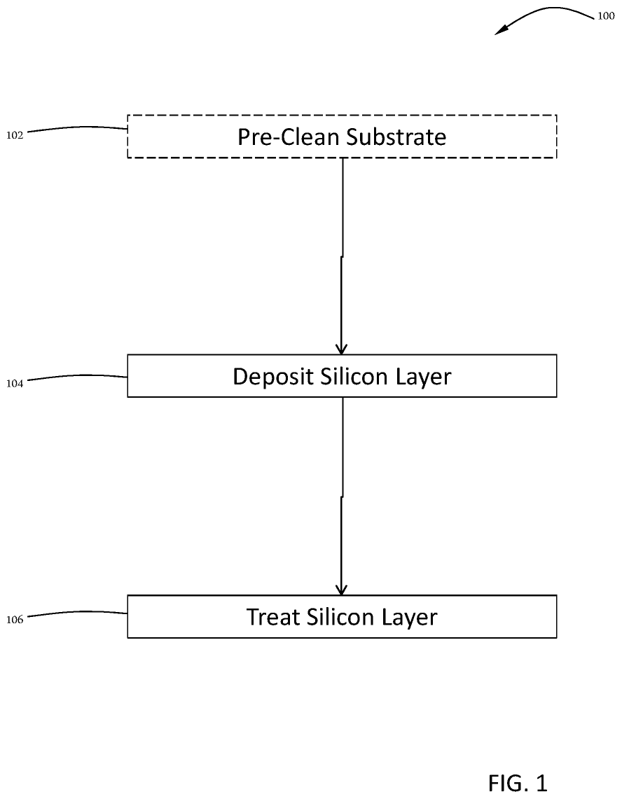

Referring to FIG. 1, the method 100 of forming a silicon cap begins at operation 104 by depositing a silicon layer at a first temperature. The silicon layer is deposited on a surface of a substrate material. In some embodiments, optional operation 102 precedes the deposition of the silicon layer.

At 102, the surface of the substrate material is cleaned. In some embodiments, cleaning the surface of the substrate material comprises exposing the surface to a remote plasma etch process. In some embodiments, the remote plasma comprises plasma of one or more of H₂, NF₃ or NH₃. In some embodiments, cleaning the surface of the substrate material comprises a SiConi etch.

In some embodiments, the substrate material comprises germanium. In some embodiments, the substrate material comprises SiGe. In some embodiments, the substrate material comprises less than or equal to about 5%, less than or equal to about 10%, less than or equal to about 15%, less than or equal to about 20%, less than or equal to about 25%, less than or equal to about 30%, less than or equal to about 35%, less than or equal to about 40%, or less than or equal to about 50% germanium on an atomic basis. In some embodiments, the substrate material comprises greater than or equal to about 2%, greater than or equal to about 5%, greater than or equal to about 10%, greater than or equal to about 15%, greater than or equal to about 20%, greater than or equal to about 25%, greater than or equal to about 30%, or greater than or equal to about 40% germanium on an atomic basis. In some embodiments, the substrate material comprises an atomic percentage of germanium in a range of about 2% to about 30%, in a range of about 5% to about 30%, in a range of about 10% to about 30%, in a range of about 15% to about 30%, in a range of about 20% to about 30%, in a range of about 25% to about 30%, in a range of about 15% to about 50%, in a range of about 20% to about 50%, in a range of about 25% to about 50%, in a range of about 30% to about 50%, or in a range of about 40% to about 50%.

In some embodiments, the silicon layer is epitaxial. In some embodiments, the silicon layer is polycrystalline. In some embodiments, the silicon layer is amorphous or substantially amorphous.

In some embodiments, the first temperature is relatively low. In some embodiments, the first temperature is less than or equal to about 700° C., less than or equal to about 650° C., less than or equal to about 600° C., less than or equal to about 550° C., less than or equal to about 500° C.

Without being bound by theory, it is believed that when the formation temperature of the silicon layer is above about 700° C., germanium atoms from the substrate material may migrate or react with the deposited layer such that germanium atoms are found within the deposited silicon layer. In some embodiments, the silicon layer comprises substantially no germanium atoms. In some embodiments, the silicon cap comprises substantially no germanium atoms.

As used in this specification and the appended claims, a material or layer which comprises substantially no atoms of a given element, comprises less than or equal to about 2%, less than or equal to about 1%, less than or equal to about 0.5%, or less than or equal to about 0.1% of the stated element on an atomic basis.

In some embodiments, the silicon layer has a thickness of less than about 5 nm, less than about 4 nm, less than about 3 nm, or less than about 2 nm. In some embodiments, the silicon layer has a thickness in a range of about 1 nm to about 5 nm, in a range of about 2 nm to about 5 nm, in a range of about 3 nm to about 5 nm, in a range of about 4 nm to about 5 nm, in a range of about 1 nm to about 4 nm, in a range of about 2 nm to about 4 nm, in a range of about 3 nm to about 4 nm, in a range of about 1 nm to about 3 nm, in a range of about 2 nm to about 3 nm, or in a range of about 1 nm to about 2 nm.

In some embodiments, the surface has a feature formed thereon. In some embodiments, the surface has a three dimensional feature formed thereon. In some embodiments, the silicon layer is substantially conformal to the surface of the substrate material. In some embodiments, the silicon cap is substantially conformal to the surface of the substrate material.

As used herein, a layer which is “substantially conformal” refers to a layer where the thickness is about the same throughout (e.g., on the top, middle and bottom of sidewalls and on the bottom of the gap). A layer which is substantially conformal varies in thickness by less than or equal to about 10%, 5%, 2%, 1% or 0.5%.

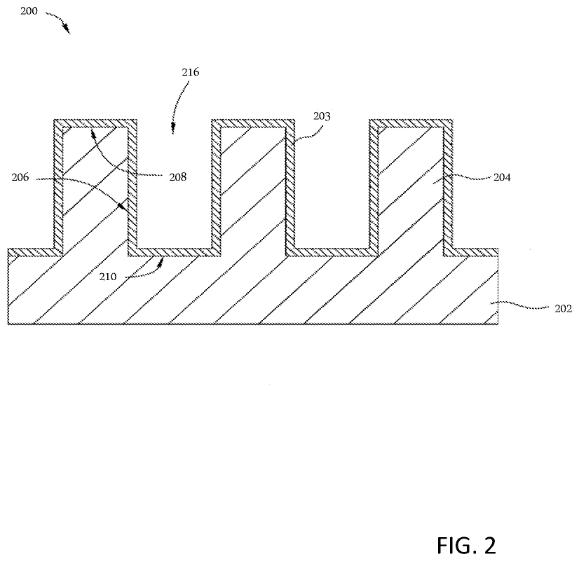

FIG. 2 illustrates an exemplary substrate 200 comprising a substrate material 202 and a substrate surface 203 having three dimensional (3D) features 204 formed thereon according to one or more embodiment described herein. The substrate 200 includes the 3D features 204 which extend from a substrate material 202. In some embodiments, the substrate material 202 may be silicon containing material, such as doped silicon. The embodiments described herein are generally made with reference to a 300 mm circular substrate, however, it is contemplated that various other substrate dimensions may benefit from the embodiments described herein.

The 3D features 204 may be formed on the substrate surface 203 of the substrate material 202 by various patterning and etching processes. Generally, the 3D features are formed with dimensions suitable for implementation as fin field-effect transistors (FinFETs) in complimentary metal-oxide semiconductor (CMOS) transistors, however, other transistor types may also benefit from the embodiments described herein. In some embodiments, the 3D features may be suitable for and may have dimensions commensurate for utilization in current technology nodes and advanced technology nodes, such as a sub-10 nm node or a 5 nm node.

The 3D features 204 extend from the substrate material 202 and are spaced apart by trenches 216. The 3D features include a top surface 208 and sidewalls 206 which extend between the top surface 208 and a bottom surface 210 of the trenches 216.

Referring again to FIG. 1, after depositing the silicon layer at operation 104, the silicon layer is treated at operation 106 to form a silicon cap. In some embodiments, the treatment of the silicon layer forms a silicon cap with reduced defects. In some embodiments, the treatment of the silicon layer forms a silicon cap with repaired bonds. In some embodiments, the treatment of the silicon layer forms a silicon cap with improved electrical properties.

Operation 106 may comprise one or more treatment processes at a second temperature. Exemplary treatment processes include, but are not limited to, thermal anneal processes like RTP, and plasma treatment processes like DPX. In some embodiments, treating the silicon layer comprises a RTP process and the second temperature is greater than or equal to about 1000° C., greater than or equal to about 1100° C., greater than or equal to about 1200° C., or greater than or equal to about 1250° C. In some embodiments, treating the silicon layer comprises a spike anneal process and the second temperature is less than or equal to about 950° C., less than or equal to about 900° C., less than or equal to about 800° C., or less than or equal to about 700° C. In some embodiments, treating the silicon layer comprises a laser anneal process and the second temperature is less than or equal to about 1200° C., less than or equal to about 1100° C., less than or equal to about 1000° C., less than or equal to about 900° C., or less than or equal to about 800° C. In some embodiments, the second temperature is in a range of about 600° C. to about 800° C. Regardless of the process used in operation 106, the second temperature is bound by the thermal budget of the device to prevent diffusion of germanium atoms into the silicon layer and/or the silicon cap.

Without being bound by theory it is believed that RTP processes conducted at relatively high second temperatures are not performed for a period of time long enough to allow for migration or reaction of germanium within the substrate material. Accordingly, in some embodiments, the silicon cap comprises substantially no germanium atoms.

In some embodiments, operations 104 and 106 are clustered together in a clustered tool. In some embodiments, operations 104 and 106 are performed without breaking vacuum between operation 104 and operation 106. In some embodiments, operation 104 and operation 106 are performed within a single processing environment.

In some embodiments, the silicon layer is not exposed to any oxidant. In some embodiments, the silicon layer comprises substantially no oxygen atoms. In some embodiments, the silicon cap is not exposed to any oxidant during operation 106. In some embodiments, the silicon cap comprises substantially no oxygen atoms.

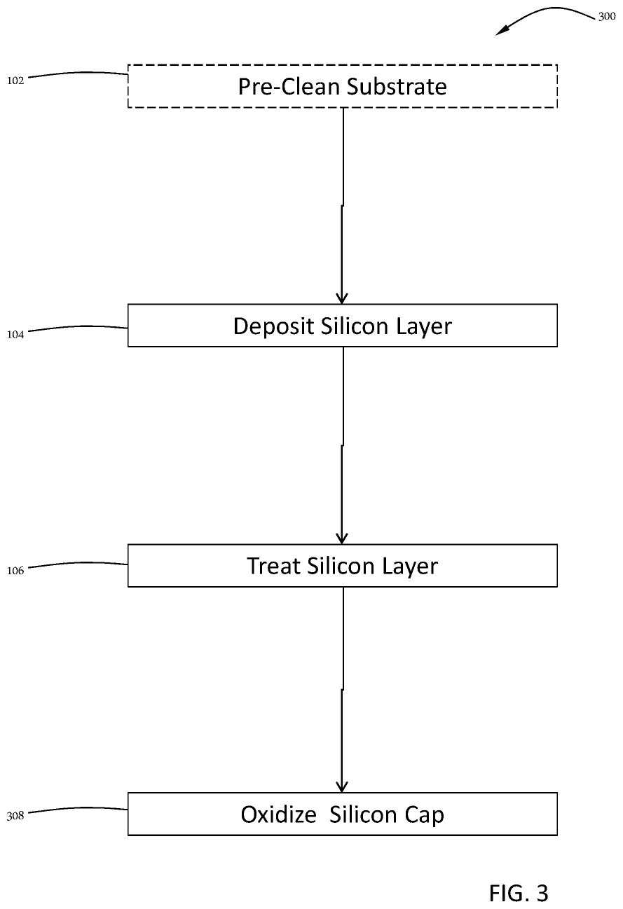

Referring to FIG. 3, some embodiments of the disclosure relate to methods of forming a silicon oxide capping layer. The method 300 comprises operations 104 and 106 as well as optional operation 102 as discussed above in relation to FIG. 1. The method 300 continues with operation 308 where the silicon cap of some embodiments is oxidized to form a silicon oxide capping layer.

In some embodiments, the silicon cap is oxidized by exposing the silicon cap to ambient oxygen. In some embodiments, the silicon cap is oxidized by a controlled oxidation process. As used in this regard, a “controlled process” is one where one or more results of the oxidation process are controlled. Results which may be controlled include, but are not limited to, the amount of oxidation, the depth of oxidation, and the directionality or conformality of oxidation.

In some embodiments, oxidizing the silicon cap comprises exposing the silicon cap to an oxidant comprising substantially no plasma. In this regard, operation 308 may be referred to as a thermal oxidation process. In some embodiments, the thermal oxidation process is performed at a temperature of less than or equal to about 700° C., less than or equal to about 650° C., less than or equal to about 600° C., or less than or equal to about 550° C. In some embodiments, the thermal oxidation process is performed at a temperature in a range of about 500° C. to about 700° C., in a range of about 550° C. to about 700° C., in a range of about 600° C. to about 700° C., in a range of about 650° C. to about 700° C., in a range of about 500° C. to about 650° C., in a range of about 550° C. to about 650° C., in a range of about 500° C. to about 600° C., in a range of about 550° C. to about 600° C., or in a range of about 500° C. to about 600° C.

In some embodiments, oxidizing the silicon cap comprises exposing the silicon cap to a plasma of an oxidant. In some embodiments, the plasma is a direct plasma. In some embodiments, the plasma is a remote plasma. In some embodiments, the plasma is a conductively coupled plasma (CCP) or an inductively coupled plasma (ICP). In some embodiments, the plasma exposure is performed at a temperature less than or equal to about 700° C., less than or equal to about 650° C., less than or equal to about 600° C., less than or equal to about 550° C., less than or equal to about 500° C., less than or equal to about 450° C., or less than or equal to about 400° C. In some embodiments, the plasma exposure is performed at a temperature in a range of about 400° C. to about 550° C., in a range of about 450° C. to about 550° C., in a range of about 500° C. to about 550° C., in a range of about 400° C. to about 500° C., in a range of about 450° C. to about 500° C., or in a range of about 400° C. to about 450° C. In some embodiments, the plasma exposure is performed at a temperature in a range of about 25° C. (i.e. room temperature) to about 550° C., in a range of 25° C. (i.e. room temperature) to about 500° C., in a range of about 50° C. to about 550° C., in a range of about 100° C. to about 550° C., in a range of about 200° C. to about 550° C., or in a range of about 300° C. to about 550° C.

In some embodiments, oxidizing the silicon cap results in a combined thickness of the silicon cap and the silicon oxide capping layer which is greater than the thickness of the silicon cap before oxidation. Stated differently, in some embodiments, oxidation of the silicon cap results in volumetric expansion to provide a greater thickness of silicon oxide capping layer than the silicon cap which was oxidized.

In some embodiments, operation 308 oxidizes the silicon cap to a predetermined depth. Stated differently, in some embodiments, operation 308 is referred to as a controllable process. As used in this regard, the depth of an oxidation process refers to the thickness of the silicon cap which is oxidized. In some embodiments, the oxidation process may oxidize about 10%, about 20%, about 25%, about 40%, about 50%, about 60%, about 75%, about 80%, about 90% or about 100% of the thickness of the silicon cap. For example, in some embodiments, a silicon cap of about 3 nm is formed and the silicon cap is oxidized to form about 4 nm of silicon oxide on 1 nm of the remaining silicon cap.

In some embodiments, operation 308 oxidizes the silicon cap to a predetermined concentration of atomic oxygen. Stated differently, in some embodiments, operation 308 is referred to as a tunable process. As used in this regard, the concentration of an oxidation process refers to the atomic concentration of oxygen in the resulting silicon oxide capping layer. In some embodiments, the resulting silicon oxide capping layer comprises an atomic ratio of silicon to oxygen of 1:2 (e.g., SiO₂). In some embodiments, the silicon oxide capping layer is an oxygen-rich layer with an atomic ratio of oxygen to silicon of greater than 2:1. In some embodiments, the silicon oxide capping layer is a silicon rich layer with an atomic ratio of silicon to oxygen of greater than 1:2.

In some embodiments, operation 308 oxidizes the silicon cap with a predetermined directionality. In some embodiments, the predetermined directionality is equal (or nearly equal) from all directions and the silicon cap is oxidized conformally.

Some embodiments of the disclosure relate to methods of forming a replacement metal gate (RMG). These embodiments comprise the methods of forming a silicon oxide capping layer described above. In some embodiments, the methods continue by depositing a dummy poly layer on the silicon oxide capping layer. In some embodiments, the methods comprise removing the dummy poly layer. In some embodiments, the methods comprise removing the silicon oxide capping layer. In some embodiments, the methods comprise forming a replacement metal gate on the silicon cap.

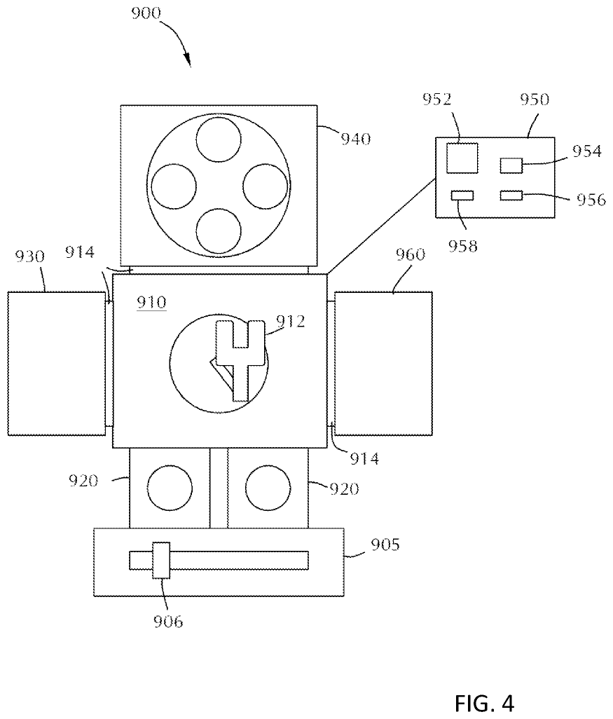

With reference to FIG. 4, additional embodiments of the disclosure are directed to a system 900 for executing the methods described herein. FIG. 4 illustrates a system 900 that can be used to process a substrate according to one or more embodiment of the disclosure. The system 900 can be referred to as a cluster tool. The system 900 includes a central transfer station 910 with a robot 912 therein. The robot 912 is illustrated as a single blade robot; however, those skilled in the art will recognize that other robot 912 configurations are within the scope of the disclosure. The robot 912 is configured to move one or more substrate between chambers connected to the central transfer station 910.

At least one pre-clean/buffer chamber 920 is connected to the central transfer station 910. The pre-clean/buffer chamber 920 can include one or more of a heater, a radical source or plasma source. The pre-clean/buffer chamber 920 can be used as a holding area for an individual semiconductor substrate or for a cassette of wafers for processing. The pre-clean/buffer chamber 920 can perform pre-cleaning processes or can pre-heat the substrate for processing or can simply be a staging area for the process sequence. In some embodiments, there are two pre-clean/buffer chambers 920 connected to the central transfer station 910.

In the embodiment shown in FIG. 9, the pre-clean/buffer chambers 920 can act as pass through chambers between the factory interface 905 and the central transfer station 910. The factory interface 905 can include one or more robot 906 to move substrate from a cassette to the pre-clean/buffer chamber 920. The robot 912 can then move the substrate from the pre-clean/buffer chamber 920 to other chambers within the system 900.

A first processing chamber 930 can be connected to the central transfer station 910. The first processing chamber 930 can be configured as a silicon deposition chamber and may be in fluid communication with one or more reactive gas sources to provide one or more flows of reactive gases to the first processing chamber 930. The substrate can be moved to and from processing chamber 930 by the robot 912 passing through isolation valve 914.

Processing chamber 940 can also be connected to the central transfer station 910. In some embodiments, processing chamber 940 comprises a treatment chamber and is fluid communication with one or more reactive gas sources to provide flows of reactive gas to the processing chamber 940 to perform the treatment process. The substrate can be moved to and from processing chamber 940 by robot 912 passing through isolation valve 914.

Processing chamber 945 can also be connected to the central transfer station 910. In some embodiments, the processing chamber 945 is the same type of processing chamber 940 configured to perform the same process as processing chamber 940. This arrangement might be useful where the process occurring in processing chamber 940 takes much longer than the process in processing chamber 930.

In some embodiments, processing chamber 960 is connected to the central transfer station 910 and is configured to act as an oxidation chamber. The processing chamber 960 can be configured to perform one or more different oxidation processes.

In some embodiments, each of the processing chambers 930, 940, 945 and 960 are configured to perform different portions of the processing method. For example, processing chamber 930 may be configured to perform the silicon deposition process, processing chamber 940 may be configured to perform the treatment process, processing chamber 945 may be configured as a metrology station or to perform a treatment process and processing chamber 960 may be configured to perform an oxidation process. The skilled artisan will recognize that the number and arrangement of individual processing chamber on the tool can be varied and that the embodiment illustrated in FIG. 9 is merely representative of one possible configuration.

In some embodiments, the system 900 includes one or more metrology stations. For example metrology stations can be located within pre-clean/buffer chamber 920, within the central transfer station 910 or within any of the individual processing chambers. The metrology station can be any position within the system 900 that allows the distance of the recess to be measured without exposing the substrate to an oxidizing environment.

At least one controller 950 is coupled to one or more of the central transfer station 910, the pre-clean/buffer chamber 920, processing chambers 930, 940, 945, or 960. In some embodiments, there are more than one controller 950 connected to the individual chambers or stations and a primary control processor is coupled to each of the separate processors to control the system 900. The controller 950 may be one of any form of general-purpose computer processor, microcontroller, microprocessor, etc., that can be used in an industrial setting for controlling various chambers and sub-processors.

The at least one controller 950 can have a processor 952, a memory 954 coupled to the processor 952, input/output devices 956 coupled to the processor 952, and support circuits 958 to communication between the different electronic components. The memory 954 can include one or more of transitory memory (e.g., random access memory) and non-transitory memory (e.g., storage).

The memory 954, or computer-readable medium, of the processor may be one or more of readily available memory such as random access memory (RAM), read-only memory (ROM), floppy disk, hard disk, or any other form of digital storage, local or remote. The memory 954 can retain an instruction set that is operable by the processor 952 to control parameters and components of the system 900. The support circuits 958 are coupled to the processor 952 for supporting the processor in a conventional manner. Circuits may include, for example, cache, power supplies, clock circuits, input/output circuitry, subsystems, and the like.

Processes may generally be stored in the memory as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 950 has one or more configurations to execute individual processes or sub-processes to perform the method. The controller 950 can be connected to and configured to operate intermediate components to perform the functions of the methods. For example, the controller 950 can be connected to and configured to control one or more of gas valves, actuators, motors, slit valves, vacuum control, etc.

The controller 950 of some embodiments has one or more configurations selected from: a configuration to move a substrate on the robot between the plurality of processing chambers and metrology station(s); a configuration to load and/or unload substrates from the system; a configuration to deposit a silicon layer; a configuration to treat a silicon layer; and a configuration to oxidize a silicon cap.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a silicon cap, the method comprising:
depositing a silicon layer on a surface of a substrate material maintained at a first temperature; and
treating the silicon layer at a second temperature without breaking vacuum to form a silicon cap comprising substantially no oxygen atoms.

2. The method of claim 1, further comprising cleaning the surface before depositing the silicon layer by exposing the surface to a remote plasma etch process.

3. The method of claim 1, wherein the substrate material comprises SiGe.

4. The method of claim 3, wherein the substrate material comprises less than or equal to about 30% germanium on an atomic basis.

5. The method of claim 3, wherein the silicon cap comprises substantially no germanium.

6. The method of claim 1, wherein the surface has a three dimensional feature formed thereon and the silicon cap is conformal to the surface.

7. The method of claim 1, wherein the silicon layer has a thickness in a range of about 1 nm to about 3 nm.

8. The method of claim 1, wherein the first temperature is less than or equal to about 700° C.

9. The method of claim 1, wherein treating the silicon layer comprises a rapid thermal processing (RTP) process and the second temperature is in a range of about 600° C. to about 800° C.

10. The method of claim 1, wherein treating the silicon layer provides a silicon cap with fewer defects or improved electrical properties.

11. The method of claim 1, further comprising oxidizing the silicon cap.

12. The method of claim 11, wherein oxidizing the silicon cap comprises exposing the silicon cap to an oxidant comprising substantially no plasma.

13. The method of claim 12, wherein exposing the silicon cap is performed at a temperature in a range of about 600° C. to about 700° C.

14. The method of claim 11, wherein oxidizing the silicon cap comprises exposing the silicon cap to a plasma of an oxidant.

15. The method of claim 14, wherein exposing the silicon cap is performed at a temperature in a range of about 25° C. to about 500° C.

16. The method of claim 11, wherein the silicon cap is oxidized to a predetermined depth.

17. The method of claim 11, wherein the silicon cap is oxidized to a predetermined concentration of atomic oxygen.

18. The method of claim 11, wherein the silicon cap is oxidized conformally.

19. A method of forming a silicon oxide capping layer, the method comprising:
conformally depositing a silicon layer on a surface of a substrate material, the surface having a three dimensional feature formed thereon, the substrate material comprising SiGe, the silicon layer having a thickness in a range of about 1 nm to about 3 nm, the silicon layer deposited at a temperature less than or equal to about 700° C., the silicon layer comprising substantially no germanium atoms;
treating the silicon layer without breaking vacuum to form a silicon cap with fewer defects and improved electrical properties relative to the silicon layer, the silicon cap comprising substantially no oxygen atoms nor germanium atoms; and
oxidizing the silicon cap to form a silicon oxide capping layer on the silicon cap by a controllable, tunable and conformal process.

20. A method of forming a gate dielectric and replacement metal gate, the method comprising:
conformally depositing a silicon layer on a surface of a substrate material, the surface having a three dimensional feature formed thereon, the substrate material comprising SiGe, the silicon layer having a thickness in a range of about 1 nm to about 3 nm, the silicon layer comprising substantially no germanium atoms;
treating the silicon layer without breaking vacuum to form a silicon cap with fewer defects and improved electrical properties relative to the silicon layer, the silicon cap comprising substantially no oxygen atoms nor germanium atoms;
oxidizing the silicon cap to form a silicon oxide capping layer on the silicon cap;
depositing a dummy poly layer on the silicon oxide capping layer;
removing the dummy poly layer and the silicon oxide capping layer; and
forming a replacement metal gate on the silicon cap.
